(19) United States
(12) Patent Application Publication
(10) Pub. No.: US 2019/0096696 A1
(43) Pub. Date: Mar. 28, 2019

(54) METHOD FOR FILLING VIA HOLE OF CERAMIC SUBSTRATE AND CERAMIC SUBSTRATE VIA HOLE FILLER FORMED THEREBY

(71) Applicant: AMOSENSE CO., LTD., Chungcheongnam-do, Cheonan-si (KR)

(72) Inventors: Kyung-Whan WOO, Yongin-si (KR); Ik-Seong PARK, Seoul (KR); Hyeon-Choon CHO, Seongnam-si (KR)

(73) Assignee: AMOSENSE CO., LTD., Chungcheongnam-do, Cheonan-si (KR)

(21) Appl. No.: 16/082,931

(22) PCT Filed: Mar. 8, 2017
(86) PCT No.: PCT/KR2017/002529

§ 371 Date: Sep. 6, 2018

(30) Foreign Application Priority Data
Mar. 8, 2016 (KR) 10-2016-0027539

(51) Int. Cl. H01L 21/48; H01L 23/373

(52) U.S. Cl. CPC H01L 21/4807; H01L 23/3735

(57) ABSTRACT

The present invention relates to a method for filling a via hole in a ceramic substrate and a filler for the via hole in the ceramic substrate filled using the same. The via hole is formed in a ceramic base material, and a conductor is formed in the via hole, melted in a vacuum state, and cooled, so that the via hole in the ceramic substrate is simply filled with the conductor without any voids. Accordingly, the manufacturing process of the ceramic substrate is simplified, manufacturing costs are reduced, the operational reliability of the ceramic substrate is improved, and stable operational reliability is secured when the ceramic substrate is used in a high-power semiconductor module.

### TECHNICAL FIELD

The present invention relates, in general, to a method for filling a via hole in a ceramic substrate and a filler for the via hole in the ceramic substrate filled using the same, and more particularly to a method for filling a via hole in a ceramic substrate without any voids and a filler for the via hole in the ceramic substrate filled using the same.

### BACKGROUND ART

Generally, as an example of a ceramic base material, a ceramic DBC (direct-bonded copper) substrate in which a metal foil such as a copper foil is integrally attached to a ceramic base material or a ceramic DPC in which a copper plating layer is formed on a ceramic base material is frequently used. The ceramic DBC substrate or the ceramic DBC substrate is used in a semiconductor power module, has a higher heat-dissipation characteristic than the case in which a lead is disposed on a conventional heat-dissipation material, and does not require an inspection process for the adhesion state of a heat-dissipation plate. Accordingly, the substrate has a merit in that a semiconductor power module having improved reliability, productivity, and consistency is provided.

The use range of the ceramic DBC substrate or the ceramic DBC substrate is gradually broadening to automotive power semiconductor modules as the number of electric vehicles increases.

The ceramic DBC substrate or the ceramic DBC substrate is manufactured by performing interfacial bonding of a ceramic base material and a copper foil using a firing process at a high temperature.

In a ceramic substrate including the ceramic DBC substrate or the ceramic DBC substrate, a via hole for electrically connecting circuit patterns formed on both surfaces of a ceramic base material is mainly formed by laser processing, and then a conductor is formed using plating or a conductive paste therein.

However, the via hole in the ceramic substrate processed using a laser gradually decreases in diameter from one surface to the other surface of the ceramic base material. Accordingly, when the conductor is formed using plating or the conductive paste therein, there are problems in that the conductor does not completely fill the via hole and in that a large number of voids is formed therein.

In the case of the ceramic substrate used for a semiconductor power module, it is necessary to secure stable operational reliability as the intensity of power used increases. In the case where the voids are formed in the via hole, when the intensity of power used is a predetermined value or higher, there is a problem in that it is difficult to secure operational reliability.

Further, in the case of the ceramic substrate, a large cavity may be formed in the conductor during the process of forming the conductor in the via hole. In this case, there is a problem in that the operational reliability of the ceramic substrate is greatly reduced.

### DISCLOSURE

### Technical Problem

The present invention has been made keeping in mind the above problems, and an object of the present invention is to provide a method for filling a via hole in a ceramic substrate without any voids by melting a conductor in the via hole in a vacuum and a filler for the via hole in the ceramic substrate filled using the same.

### Technical Solution

A method for filling a via hole in a ceramic substrate according to an embodiment of the present invention includes a via-hole-forming step of forming the via hole in a ceramic base material, a conductor-forming step of forming a conductor in the via hole, and a vacuum-melting step of melting the conductor in a vacuum state and cooling the conductor.

The via-hole-forming step may include forming the via hole through both surfaces of the ceramic base material using laser processing. The via hole may gradually decrease in diameter from one surface to the other surface.

The conductor-forming step may include a first deposition process of forming a first-deposition conductive layer on an inner peripheral surface of the via hole using a physical deposition method, a second deposition process of forming a second-deposition conductive layer on the first-deposition conductive layer in the via hole using the physical deposition method, and a plating process of forming a plating body in the via hole using plating, and the vacuum-melting step may include melting the plating body in a vacuum.

The physical deposition method may be one selected from among vacuum deposition, thermal deposition (evaporation), e-beam deposition, laser deposition, sputtering, and arc ion plating.

The conductor-forming step may include forming electrode layers for forming circuit patterns on both surfaces of the ceramic base material together.

The first deposition process may include forming a first-deposition electrode layer by depositing the first-deposition electrode layer on a surface of a ceramic base material together with the first-deposition conductive layer, the second deposition process may include forming a second-deposition electrode layer by depositing the second-deposition electrode layer on the first-deposition electrode layer together with the second-deposition conductive layer, and the plating process may include forming a plating electrode layer on the second-deposition electrode layer together with a conductor by plating so as to form the electrode layers for forming circuit patterns on both surfaces of the ceramic base material together.

The method for filling the via hole in the ceramic substrate according to the embodiment of the present invention may further include, after a vacuum-melting step, polishing the electrode layers to thus perform planarization.

A filler for a via hole in a ceramic substrate according to an embodiment of the present invention includes a conductor filling the via hole of a ceramic base material and having a melting structure that is cured after a metal is melted.

The conductor may be formed so as to completely fill the via hole, and may include a first-deposition conductive layer formed on an inner peripheral surface of the via hole by deposition, a second-deposition conductive layer formed on the first-deposition conductive layer by deposition, and a plating body formed in the via hole, and the plating body may fill the via hole while coming into contact with the second-deposition conductive layer, and may have a melting structure that is cured after the metal is melted.

The filler for the via hole in the ceramic substrate according to the embodiment of the present invention may further include electrode layers formed in order to form circuit patterns on both surfaces of the ceramic base material.

The electrode layers may include first-deposition electrode layers deposited on both surfaces of the ceramic base material, second-deposition electrode layers deposited on the first-deposition electrode layers on both surfaces of the ceramic base material, and plating electrode layers plated on the second-deposition electrode layers.

The via hole may gradually decrease in diameter from one surface to the other surface.

### Advantageous Effects

In the present invention, since a conductor is melted in a vacuum in a via hole to thus simply fill the via hole in a ceramic substrate without any voids, the manufacturing process of the ceramic substrate is simplified and manufacturing costs are reduced.

In the present invention, a via hole in a ceramic substrate is completely filled with a conductor without any voids, thereby improving the operational reliability of the ceramic substrate and securing stable operational reliability when the ceramic substrate is used in a high-power semiconductor module.

### DESCRIPTION OF DRAWINGS

FIG. 1 is a process view showing an embodiment of a method for filling a via hole in a ceramic substrate according to the present invention;

FIG. 2 is a schematic view showing the embodiment of the method for filling the via hole in the ceramic substrate according to the present invention; and

FIG. 3 is a cross-sectional view showing an embodiment of a filler for a via hole in a ceramic substrate according to the present invention.

### BEST MODE

The invention will be described in detail with reference to the accompanying drawings. A repeated description and a detailed description of known functions and configurations that may obscure the gist of the present invention will be omitted. Embodiments of the present invention are provided to more fully describe the present invention to those skilled in the art. Accordingly, the shapes and sizes of the elements in the drawings and the like can be exaggerated for clarity.

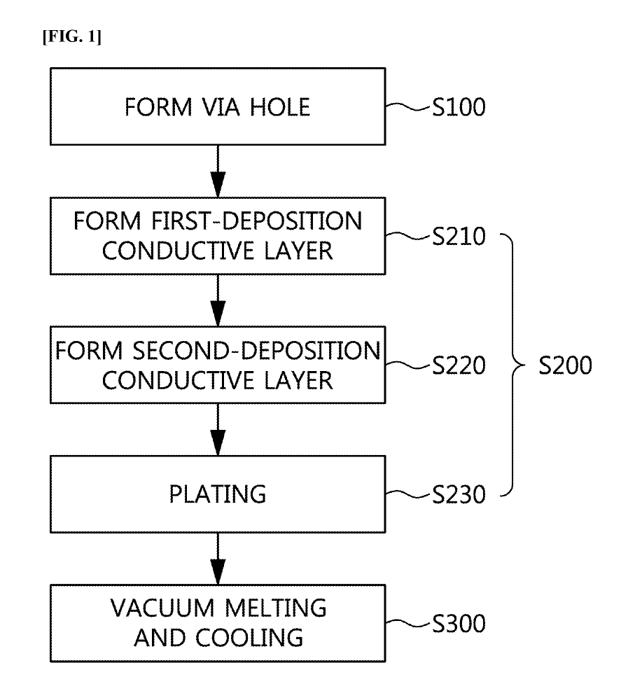

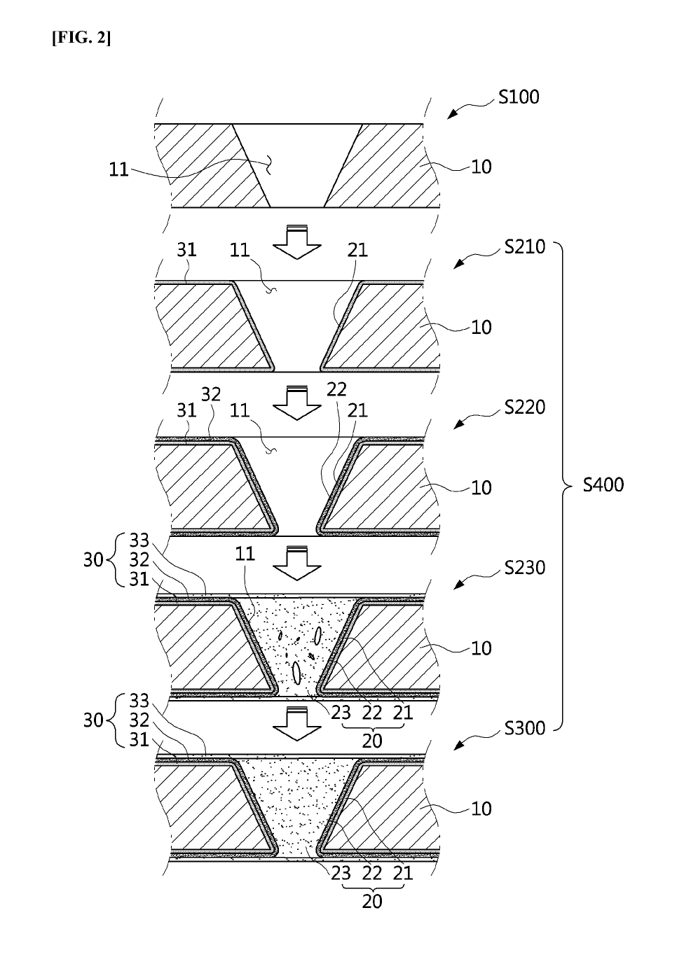

FIG. 1 is a process view showing an embodiment of a method for filling a via hole in a ceramic substrate according to the present invention, and FIG. 2 is a schematic view showing the embodiment of the method for filling the via hole in the ceramic substrate according to the present invention.

Referring to FIGS. 1 and 2, a method for filling a via hole in a ceramic substrate according to an embodiment of the present invention includes a via-hole-forming step of forming a via hole 11 in a ceramic base material 10 at step S100, a conductor-forming step of forming a conductor 20 in the via hole 11 at step S200, and a vacuum-melting step of melting the conductor 20 in a vacuum state and cooling the conductor 20 at step S300.

The via-hole-forming step includes, for example, forming the via hole 11 through both surfaces of the ceramic base material 10 using laser processing at step S100.

The via-hole-forming step may be performed using drill processing instead of laser processing at step S100.

In the via-hole-forming step at step S100, the via hole is formed in a necessary portion of the ceramic base material 10 (that is, a position in accordance with a predetermined circuit design) using one method selected from among drill processing and laser processing. The via hole 11 is formed in order to electrically connect circuit patterns formed on both surfaces of the ceramic base material 10.

In the via-hole-forming step at step S100, when the via hole 11 is formed using a laser, for example, the via hole gradually decreases in diameter from one surface to the other surface.

The conductor-forming step includes forming the conductor 20 in the via hole 11 in order to electrically connect the circuit patterns formed on both surfaces of the ceramic base material 10 at step S200. In the conductor-forming step at step S200, for example, the conductor 20 is formed in the via hole 11 by plating. In the conductor-forming step at step S200, as another example, the via hole 11 is filled with a conductive paste including conductive powder and a binder to thus form the conductor 20.

The conductor-forming step at step S200 may include a first deposition process of forming a first-deposition conductive layer 21 on the inner peripheral surface of the via hole 11 using a physical deposition method at step S210, a second deposition process of forming a second-deposition conductive layer 22 on the first-deposition conductive layer 21 in the via hole 11 using the physical deposition method at step S220, and a plating process of forming a plating body 23 in the via hole 11 using plating at step S230.

In the conductor-forming step at step S200, the first-deposition conductive layer 21 and the first-deposition conductive layer 21 are each formed to a thickness of more than 0 μm and 10 μm or less using the physical deposition method. The physical deposition method is, for example, any one among vacuum deposition, thermal deposition (evaporation), e-beam deposition, laser deposition, sputtering, and arc ion plating.

The first deposition process includes forming the first-deposition conductive layer 21 having excellent bonding force with the ceramic base material 10 by physically depositing a target material on the inner peripheral surface of the via hole 11 at step S210. The target material is, for example, a material, such as titanium (Ti), having excellent bonding force with the ceramic base material 10.

Further, the second deposition process includes forming the second-deposition conductive layer 22 by physically depositing a target material on the inner peripheral surface of the via hole 11 at step S220. The second deposition process includes forming the second-deposition conductive layer 22 having excellent bonding force with the plating body 23 by physically depositing the target material on the first-deposition conductive layer 21 on the inner peripheral surface of the via hole 11 at step S220.

In the second deposition process at step S220, copper (Cu), silver (Ag), gold (Au), or aluminum (Al), having excellent bonding force with the plating body 23 formed in the via hole 11, is used as the target material.

It is noted that the target material may be variously modified depending on the plating body 23 formed by plating in the second deposition process at step S220.

It is noted that electrode layers 30 for forming the circuit patterns on both surfaces of the ceramic base material 10 may be also formed in the conductor-forming step at step S200.

That is, the electrode layers 30 for forming the circuit patterns on both surfaces of the ceramic base material 10 may be formed during all of the first deposition process at step S210, the second deposition process at step S220, and the plating process at step S230.

In the first deposition process at step S210, the first-deposition electrode layer 31 is formed by deposition on one surface of the ceramic base material 10 together with the first-deposition conductive layer 21.

In the second deposition process at step S220, the second-deposition electrode layer 32 is formed by deposition on the first-deposition electrode layer 31 together with the second-deposition conductive layer 22.

The plating process includes forming a plating electrode layer 33 by plating on the second-deposition electrode layer 32 together with the conductor 20 at step S230.

Further, it is noted that the electrode layers 30 for forming the circuit patterns on both surfaces of the ceramic base material 10 may be separately formed by performing the plating process at step S230 in the state in which both surfaces of the ceramic base material 10 are masked.

In this case, the first-deposition electrode layer 31 and the second-deposition electrode layer 32 formed at the periphery of the via hole 11 on both surfaces of the ceramic base material 10 may be removed by etching if necessary.

In the plating process at step S230, the plating body 23 is formed in the via hole 11 using one method selected from among electroplating and electroless plating.

The plating body 23 is, for example, one selected from among copper (Cu), silver (Ag), gold (Au), and aluminum (Al), or an alloy including one or more selected from among copper (Cu), silver (Ag), gold (Au), and aluminum (Al).

In addition, it is noted that in the plating process S230, it is possible to use any material capable of forming the plating body 23 for electrically connecting the circuit patterns formed on both surfaces of the ceramic base material 10 in the via hole 11 by plating.

In the plating process at step S230, voids or cavities may be formed in the plating body 23. Particularly, when the via hole 11 gradually decreases in diameter from one surface to the other surface, more voids or cavities may be formed in the plating body 23. This is because the portion having a small diameter is filled first and the portion having a large diameter is filled later during plating, so that voids or cavities are more easily formed in the plating body 23.

In the vacuum-melting step at step S300, the ceramic base material 10 is disposed in a vacuum chamber in a vacuum state and the conductor 20 is heated to thus be melted. The melting includes a melting process and a process of cooling and then curing the melted conductor 20.

Thus, in the vacuum-melting step at step S300, voids or cavities formed in the conductor 20 are removed, thus completely filling the via hole 11 with the conductor 20.

The vacuum-melting step includes melting the plating body 23 in a vacuum at step S300. For example, when the plating body 23 is copper, the plating body 23 is heated at 800 to 1200° C. to thus be melted.

In the vacuum-melting step at step S300, the conductor 20 is heated to a melting point or higher in a vacuum state to thus be melted, whereby voids or cavities in the conductor 20 are removed.

In the vacuum-melting step at step S300, only the plating body 23 may be locally heated.

Further, the step of forming the conductor 20 at step S200 may further include, after the vacuum-melting step at step 300, polishing the electrode layers 30 to thus perform planarization (not shown) when the electrode layers 30 for forming the circuit patterns are formed together on both surfaces of the ceramic base material 10.

This is because a part of the electrode layer 30 may be melted together with the conductor 20 to thus form irregular protrusions on the surface in the vacuum-melting step at step S300.

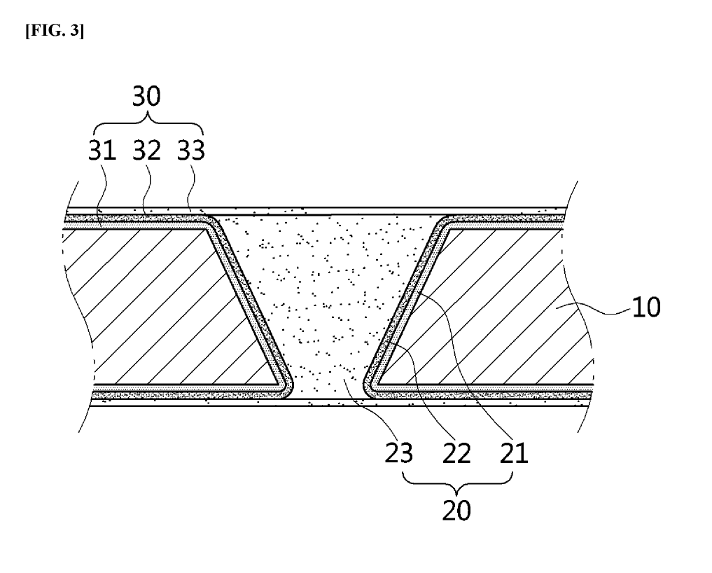

FIG. 3 is a cross-sectional view showing an embodiment of a filler for a via hole in a ceramic substrate according to the present invention.

Referring to FIG. 3, a filler for a via hole in a ceramic substrate filled using the method for filling the via hole in the ceramic substrate according to the present invention includes a conductor 20 filling the via hole 11 in the ceramic base material 10. The conductor 20 has a melting structure that is cured after a metal is melted.

Further, the conductor 20 includes a first-deposition conductive layer 21 formed on the inner peripheral surface of the via hole 11 by deposition, a second-deposition conductive layer 22 formed on the first-deposition conductive layer 21 by deposition, and a plating body 23 formed in the via hole 11. For example, the plating body 23 fills the via hole 11 while coming into contact with the second-deposition conductive layer 22.

Further, the filler for the via hole in the ceramic substrate according to the present invention includes electrode layers 30 formed in order to form circuit patterns on both surfaces of a ceramic base material 10. The electrode layers 30 may include first-deposition electrode layers 31 deposited on both surfaces of the ceramic base material 10, second-deposition electrode layers 32 deposited on the first-deposition electrode layers 31 on both surfaces of the ceramic base material 10, and plating electrode layers 33 plated on the second-deposition electrode layers 32.

The conductor 20 is formed so as to completely fill the via hole 11, and thus has no void or cavity therein.

In the embodiment of the present invention, the conductor 20 in the via hole 11 may be melted in a vacuum to thus simply fill the via hole 11 in the ceramic substrate without any voids, whereby the manufacturing process of the ceramic substrate is simplified and manufacturing costs are reduced.

In the embodiment of the present invention, the conductor 20 completely fills the via hole 11 in the silver ceramic substrate without any voids, thereby improving the operational reliability of the ceramic substrate and securing stable operational reliability when the ceramic substrate is used in a high-power semiconductor module.

Although preferred embodiments of the present invention have been described above, the present invention may be modified in various forms, and it should be understood that those skilled in the art can implement various modifications and changes without departing from the accompanying claims of the present invention.

1. A method for filling a via hole in a ceramic substrate, the method comprising:
a via-hole-forming step of forming the via hole in a ceramic base material;
a conductor-forming step of forming a conductor in the via hole; and
a vacuum-melting step of melting the conductor in a vacuum state and cooling the conductor.

2. The method of claim 1, wherein the via-hole-forming step includes forming the via hole through both surfaces of the ceramic base material using laser processing.

3. The method of claim 1, wherein the via hole gradually decreases in diameter from one surface to another surface.

4. The method of claim 1, wherein the conductor-forming step includes:
a first deposition process of forming a first-deposition conductive layer on an inner peripheral surface of the via hole using a physical deposition method;
a second deposition process of forming a second-deposition conductive layer on the first-deposition conductive layer in the via hole using the physical deposition method; and
a plating process of forming a plating body in the via hole using plating, and
the vacuum-melting step includes melting the plating body in a vacuum.

5. The method of claim 4, wherein the physical deposition method is one selected from among vacuum deposition, thermal deposition (evaporation), e-beam deposition, laser deposition, sputtering, and arc ion plating.

6. The method of claim 4, wherein the first deposition process includes forming a first-deposition electrode layer by depositing the first-deposition electrode layer on a surface of a ceramic base material together with the first-deposition conductive layer, the second deposition process includes forming a second-deposition electrode layer by depositing the second-deposition electrode layer on the first-deposition electrode layer together with the second-deposition conductive layer, and the plating process includes forming a plating electrode layer on the second-deposition electrode layer together with a conductor by plating so as to form the electrode layers for forming circuit patterns on both surfaces of the ceramic base material together.

7. The method of claim 1, wherein the conductor-forming step includes forming electrode layers for forming circuit patterns on both surfaces of the ceramic base material together.

8. The method of claim 6, further comprising:
after the vacuum-melting step, polishing the electrode layers to thus perform planarization.

9. The method of claim 7, further comprising:
after the vacuum-melting step, polishing the electrode layers to thus perform planarization.

10. A filler for a via hole in a ceramic substrate, comprising:
a conductor filling the via hole in a ceramic base material and having a melting structure that is cured after a metal is melted.

11. The filler of claim 10, wherein the conductor is formed so as to completely fill the via hole.

12. The filler of claim 10, wherein the conductor includes a first-deposition conductive layer formed on an inner peripheral surface of the via hole by deposition, a second-deposition conductive layer formed on the first-deposition conductive layer by deposition, and a plating body formed in the via hole, and the plating body fills the via hole while coming into contact with the second-deposition conductive layer and has the melting structure that is cured after the metal is melted.

13. The filler of claim 10, wherein the filler includes electrode layers formed in order to form circuit patterns on both surfaces of the ceramic base material.

14. The filler of claim 13, wherein the electrode layers include
first-deposition electrode layers deposited on the both surfaces of the ceramic base material;
second-deposition electrode layers deposited on the first-deposition electrode layers on the both surfaces of the ceramic base material; and
plating electrode layers plated on the second-deposition electrode layers.

15. The filler of claim 10, wherein the via hole gradually decreases in diameter from one surface to another surface.
